(19) United States
(12) Patent Application Publication
(10) Pub. No.: US 2024/0037178 A1
(43) Pub. Date: Feb. 1, 2024

(54) COMPUTE-IN-MEMORY CIRCUIT WITH CHARGE-DOMAIN PASSIVE SUMMATION AND ASSOCIATED METHOD

(71) Applicant: MEDIATEK INC., Hsin-Chu (TW)

(72) Inventor: Sung-En Hsieh, Hsinchu City (TW)

(73) Assignee: MEDIATEK INC., Hsin-Chu (TW)

(21) Appl. No.: 18/215,175

(22) Filed: Jun. 28, 2023

Related U.S. Application Data
(60) Provisional application No. 63/369,673, filed on Jul. 28, 2022.
(60) Provisional application No. 63/369,674, filed on Jul. 28, 2022.

(51) Int. Cl. G06F 17/11

(52) U.S. Cl. CPC G06F 17/11

(57) ABSTRACT

A compute-in-memory (CIM) circuit includes a processing circuit. The processing circuit includes a data-selection circuit and a charge-domain passive summation circuit. The data-selection circuit includes a memory array and a selection circuit. The memory array stores a plurality of candidate weights. The selection circuit selects a target weight from the plurality of candidate weights stored in the memory array. The charge-domain passive summation circuit generates an analog computation result of an input received by the processing circuit and the target weight stored in the memory array through a weighted capacitor array integrated with the memory array.

### CROSS REFERENCE TO RELATED APPLICATIONS

This application claims the benefit of U.S. Provisional Application No. 63/369,673, filed on Jul. 28, 2022. Further, this application claims the benefit of U.S. Provisional Application No. 63/369,674, filed on Jul. 28, 2022. The contents of these applications are incorporated herein by reference.

### BACKGROUND

The present invention relates to a compute-in-memory (CIM) design, and more particularly, to a CIM circuit with charge-domain passive summation and an associated method.

A convolutional neural network (CNN) used by an artificial intelligence (AI) application is made up of neurons that have learnable weights. Each neuron receives AI inputs, and performs a dot product (i.e., a convolution operation) upon AI inputs and weights. One conventional approach may employ a central processing unit (CPU) to deal with the convolution operations, which is not a power-efficient solution. Another conventional approach may employ a bit-wise current-based or time-based compute-in-memory (CIM) circuit to deal with the convolution operations, which is neither a power-efficient solution nor a high-accuracy solution. Thus, there is a need for an innovative CIM design with low power consumption and high accuracy.

### SUMMARY

One of the objectives of the claimed invention is to provide a CIM circuit with charge-domain passive summation and an associated method.

According to a first aspect of the present invention, an exemplary CIM circuit is disclosed. The exemplary CIM circuit includes a processing circuit. The processing circuit includes a data-selection circuit and a charge-domain passive summation circuit. The data-selection circuit includes a memory array and a selection circuit. The memory array is arranged to store a plurality of candidate weights. The selection circuit is arranged to select a target weight from the plurality of candidate weights stored in the memory array. The charge-domain passive summation circuit is arranged to generate an analog computation result of an input received by the processing circuit and the target weight stored in the memory array through a weighted capacitor array integrated with the memory array.

According to a second aspect of the present invention, an exemplary CIM method is disclosed. The exemplary CIM method includes: storing a plurality of candidate weights in a memory array; selecting a target weight from the plurality of candidate weights; and performing, by a weighted capacitor array integrated with the memory array, charge-domain passive summation to generate an analog computation result of an input and the target weight.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a compute-in-memory (CIM) circuit according to an embodiment of the present invention.

FIG. 2 is a diagram illustrating a circuit design of a processing circuit used by the CIM circuit shown in FIG. 1 according to an embodiment of the present invention.

FIG. 3 is a diagram illustrating calibration of different external analog buffers of a CIM circuit according to an embodiment of the present invention.

FIG. 4 is a diagram illustrating inter-buffer mismatch between different external analog buffers.

FIG. 5 is a diagram illustrating additional calibration of different external analog buffers of a CIM circuit according to an embodiment of the present invention.

FIG. 6 is a diagram illustrating deviation between aligned transfer curves of different external analog buffers and an ideal curve before reference voltage tuning.

FIG. 7 is a diagram illustrating that the aligned transfer curves of different external analog buffers are the same as the ideal curve after reference voltage tuning.

FIG. 8 is a diagram illustrating per-layer calibration of different external analog buffers of a CIM circuit according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

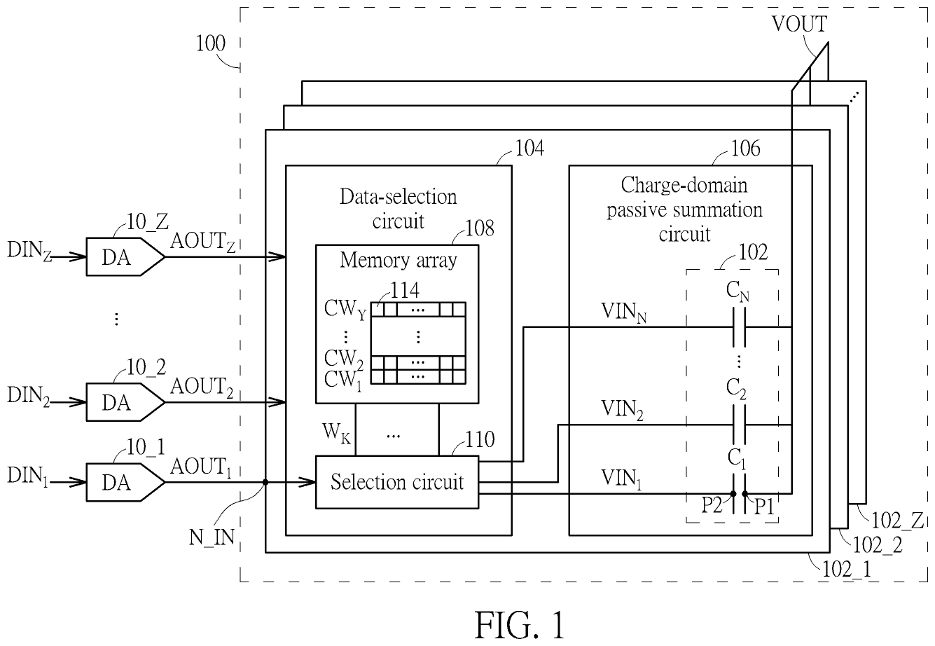

FIG. 1 is a diagram illustrating a CIM circuit according to an embodiment of the present invention. The CIM circuit 100 includes a plurality of processing circuits 102_1, 102_2, . . . , 102_Z used to process a plurality of inputs, respectively. By way of example, but not limitation, the processing circuits 102_1-102_Z (Z≥2) may have the same circuit architecture. Taking the processing circuit 102_1 for example, it may include a data-selection circuit 104 and a charge-domain passive summation circuit 106. The data-selection circuit 104 may include a memory array 108 and a selection circuit 110. The charge-domain passive summation circuit 106 may include a weighted capacitor array 112. As shown in FIG. 1, the weighted capacitor array 112 includes a plurality of capacitors C₁, C₂, . . . , C_{N} with different capacitance values. The memory array 108 includes a plurality of memory cells 114, and is arranged to store a plurality of candidate weights CW₁, CW₂, . . . , CW_{Y}. Each of the candidate weights CW₁-CW_{Y} (Y≥2) may be an X-bit weight CWᵢ[X−1:0] (i={1,2, . . . ,Y} & X≥2) and each bit of the X-bit weight CWᵢ[X−1:0] is stored in one memory cell 114 of the memory array 108. For example, the memory array 108 may be a static random access memory (SRAM) array, and each of the memory cells 114 may be an SRAM cell. However, this is for illustrative purposes only, and is not meant to be a limitation of the present invention. In practice, the memory type of the memory array 108 may be adjusted, depending upon actual design considerations.

It should be noted that the present invention has no limitations on the arrangement of word lines (WLs) and bit lines (BLs) of the memory array 108. In one exemplary implementation, the memory array 108 may be designed to have WLs in a horizontal direction and BLs in a vertical direction. In another exemplary implementation, the memory array 108 may be designed to have WLs in a vertical direction and BLs in a horizontal direction.

In some embodiments of the present invention, the CIM circuit 100 may be an analog CIM (ACIM) circuit used by an artificial intelligence (AI) application, and the candidate weights CW₁-CW_{Y} may be weights of a neural network such as a convolutional neural network (CNN). The selection circuit 110 is arranged to select a target weight Wₖ (k={1,2, . . . ,Z}) from the candidate weights CW₁-CW_{Y} stored in the memory arrayl08. For example, the selection circuit 110 of the processing circuit 102_1 may select a target weight W₁ (i.e., Wₖ with k=1) being one of the candidate weights CW₁-CW_{Y}, the selection circuit 110 of another processing circuit 102_2 may select a target weight W₂ (i.e., Wₖ with k=2) being one of the candidate weights CW₁-CW_{Y}, and the selection circuit 110 of yet another processing circuit 102_Z may select a target weight W_{Z} (i.e., Wₖ with k=Z) being one of the candidate weights CW₁-CW_{Y}. The target weights selected and used by different processing circuits 102_1-102_Z may be the same or may be different from each other. In a case where the CIM circuit 100 is used by an AI application, the CIM circuit 100 may be used to act as one neuron in the CNN, and may be reused to act as another neuron in the CNN. Hence, the candidate weights CW₁-CW_{Y} may include weights of different neurons in the CNN.

In this embodiment, the CIM circuit 100 is an ACIM circuit that uses the charge-domain passive summation circuit 106 to generate an analog computation result of an analog input AOUT₁ (i.e., AOUTₖ with k=1) received by the processing circuit 102_1 and the target weight W₁ (i.e., Wₖ with k=1, which is one of the candidate weights CW₁-CW_{Y} stored in the memory array 108) through the weighted capacitor array 112 with a particular capacitance ratio, where the particular capacitance ratio may be adjusted, depending upon actual design considerations. For example, capacitors C₁-C_{N} of the weighted capacitor array 112 maybe implemented using MOM (Metal-Oxide-Metal) capacitors, and thus occupy a large layout area in a chip. In this embodiment, the weighted capacitor array 112 of the charge-domain passive summation circuit 106 can be shared among multiple candidate weights CW₁-CW_{Y} stored in the memory array 108. Hence, the weighted capacitor array 112 can be integrated with the memory array 108 for area optimization. Specifically, in a vertical direction of an integrated circuit, the weighted capacitor array 112 implemented using MOM capacitors may overlay memory cells 114 of the memory array 108 that are used to store the candidate weights CW₁-CW_{Y}.

In this embodiment, the processing circuits 102_1-102_Z are arranged to receive a plurality of analog inputs AOUT₁, AOUT₂, AOUT_{z} output from a plurality of external analog buffers 10_1, 10_2, . . . , 10_Z, respectively. For example, each of the external analog buffers 10_1-10_Z may be implemented using a digital-to-analog converter (labeled by “DA”). Hence, the analog inputs AOUT₁, AOUT₂, . . . , AOUT_{z} are generated by converting a plurality of digital codes DIN1, DIN2, . . . , DIN_{z} from a digital domain to an analog domain. Since inputs of the processing circuits 102_1-102_Z are analog signals, node (energy) reduction can be achieved. For example, the processing circuit 102_1 requires only a single node N_IN for receiving only a single analog input AOUT₁ (which has a specific voltage level representative of the digital code DIN₁) from the external analog buffer 10_1, such that the input power dissipation (fCV²) can be greatly reduced.

As mentioned above, each of the candidate weights CW₁-CW_{Y} (Y≥2) may be an X-bit weight CWᵢ[X−1:0] & X≥2) and each bit of the X-bit weight CWᵢ[X−1:0] is stored in one memory cell 114 of the memory array 108. Hence, the target weight W₁ (i.e., Wₖ with k=1) has a plurality of bits W₁[X−1:0] stored in memory cells 114 in the memory array 108, respectively. In this embodiment, the selection circuit 110 is further arranged to selectively apply the analog input AOUT₁ to capacitors C₁-C_{N} according to bits W₁[X−1:0], respectively. For example, the weighted capacitor array 112 is a binary-weighted capacitor array (N=X−1) consisting of capacitors C_{N}=2^{X-1}C, . . . , C₂=2C, and C₁=1C. When W₁[i] (i={1,2, . . . ,X−1}) is equal to 1, the selection circuit 110 allows the analog input AOUT₁ to be delivered to a capacitor Cᵢ of the binary-weighted capacitor array 112 (i.e., VINᵢ=AOUT₁). When W₁[i] (i={1,2, . . . ,X−1}) is equal to 0, the selection circuit 110 blocks the analog input AOUT₁ from being delivered to the capacitor Cᵢ of the binary-weighted capacitor array 112, and allows a reference voltage (e.g., ground voltage GND) to be delivered to the capacitor Cᵢ of the binary-weighted capacitor array 112 (i.e., VINᵢ=GND). In this embodiment, the selection circuit 110 is arranged to control transmission of the analog input AOUT₁ by referring to the bits W₁[X−1:0] concurrently, thereby enabling a direct multi-bit operation for setting the analog computation result at the charge-domain passive summation circuit 106. Hence, the charge-domain passive summation circuit 106 (particularly, weighted capacitor array 112 of charge-domain passive summation circuit 106) of the processing circuit 102_1 generates an analog computation result (which is an analog output of DIN₁×W₁[X−1:0]) by combining the voltage signals VIN₁-VIN_{N} through charge redistribution among the binary-weighted capacitor array C_{N}=2^{X-1}C, . . . , C₂=2C, and C₁=1C. Since the analog computation result is set by controlling voltage signals VIN₁-VIN_{N} applied to capacitors C₁-C_{N} of the weighted capacitor array 112 according to bits W₁[X−1:0], the analog computation result with high accuracy can be generated from the processing circuit 102_1.

Similarly, the charge-domain passive summation circuit 106 (particularly, weighted capacitor array 112 of charge-domain passive summation circuit 106) of anther processing circuit 102_2 generates an analog computation result (which is an analog output of DIN₂×W₂[X−1:0]) by combining the voltage signals VIN₁-VIN_{N} through charge redistribution among the binary-weighted capacitor array C_{N}=2^{X-1}C, . . . , C₂=2C, and C₁=1C; and the charge-domain passive summation circuit 106 (particularly, weighted capacitor array 112 of charge-domain passive summation circuit 106) of yet another processing circuit 102_Z generates an analog computation result (which is an analog output of DIN_{Z}×W_{Z}[X−1:0]) by combining the voltage signals VIN₁-VIN_{N} through charge redistribution among the binary-weighted capacitor array C_{N}=2^{X-1}C, . . . , C₂=2C, and C₁=1C.

As shown in FIG. 1, each of the capacitors C₁-C_{N} has a top plate P1 and a bottom plate P2, and top plates P1 of capacitors C₁-C_{N} included in the weighted capacitor arrays 112 of all processing circuits 102_1-102_Z are directly connected without selection. The output voltage VOUT (which is an analog output of Σₖ₌₁^{Z}DINₖ×Wₖ[X−1:0]) can be obtained by means of such a simple design.

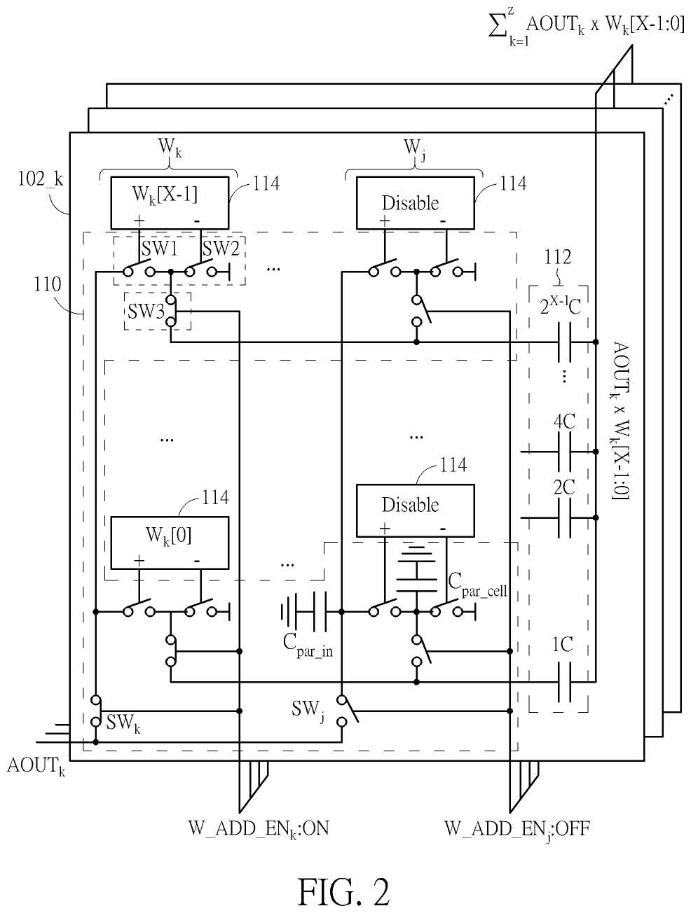

For better comprehension of technical features of the present invention, an exemplary circuit design of a processing circuit used by the proposed CIM circuit 100 is illustrated in FIG. 2. The processing circuit 102_k (k={1,2, . . . ,Z}) shown in FIG. 2 may be any of the processing circuits 102_1-102_Z shown in FIG. 1. In this embodiment, the candidate weights CW₁-CW_{Y} may be stored in memory cell lines (e.g., memory cell rows or memory cell columns), respectively; and candidate weights included in the candidate weights CW₁-CW_{Y} that are not selected as the target weight Wₖ used by the processing circuit 102_k are collectively represented by Wⱼ. The selection circuit 110 may be a switch-based circuit including a plurality of switches that maybe implemented using P-channel metal-oxide-semiconductor (PMOS) transistors or N-channel metal-oxide-semiconductor (NMOS) transistors, and may be integrated with the memory array 108. As shown in FIG. 2, the selection circuit 110 includes a plurality of global selection switches SWₖ and SWⱼ, where the global selection switch SWₖ corresponds to a candidate weight that is selected as the target weight Wₖ, and the global selection switch SWⱼ corresponds to any candidate weight that is not selected as the target weight Wₖ. Specifically, the global selection switch SWₖ is shared among memory cells that store bits of a candidate weight that is selected as the target weight Wₖ, and the global selection switch SWⱼ is shared among memory cells that store bits of a candidate weight that is not selected as the target weight Wₖ. In addition, the selection circuit 110 includes a plurality of local selection switches for each memory cell that stores one bit of the candidate weights CW₁-CW_{Y}. Taking the memory cell that stores the bit Wₖ[X−1] for example, there are two weight switches SW1 and SW2 and one cell switch SW3. However, this is for illustrative purposes only, and is not meant to be a limitation of the present invention. In practice, the number of local selection switches for each memory cell may be adjusted, depending upon actual design considerations.

Each of the global selection switches SWₖ and SWⱼ has one terminal that is arranged to receive the analog input AOUTₖ from an external analog buffer (not shown). One of the global selection switches that corresponds to a memory cell line (e.g., memory cell row or memory cell column) in which the target weight Wₖ is stored is switched on, and the rest of the global selection switches are switched off. In this embodiment, one switch control signal W_ADD_ENₖ may be asserted to switch on the global selection switch SWₖ, and another switch control signal W_ADD_ENⱼ may be deasserted to switch off the global selection switch SWⱼ. Though the candidate weight Wⱼ is not selected as the target weight Wₖ, the memory cells that store bits of the candidate weight Wⱼ may include input parasitic capacitance C_{par_in}. By switching off the global selection switch SWⱼ, the power dissipation resulting from input parasitic capacitance C_{par_in} of memory cells that stores bits of the candidate weight Wⱼ can be prevented to achieve energy reduction/power saving.

Suppose that the memory array 108 is an SRAM array, and each of the memory cells 114 is an SRAM cell. Hence, each memory cell 114 may have two bit lines BL and B̅L̅, where a voltage level at the bit line BL (which is labeled by “+” in FIG. 2) is set based on the bit stored in the memory cell 114, and a voltage level at the bit line B̅L̅ (which is labeled by “−” in FIG. 2) is set based on an inverse of the bit stored in the memory cell 114. Regarding a memory cell that stores one bit of the target weight Wₖ, the weight switches SW1 and SW2 (which are local selection switches of the memory cell) are controlled by the bit stored in the memory cell. Taking the weight switches SW1 and SW2 of the memory cell that stores the bit Wₖ[X−1] for example, the weight switch SW1 is controlled by the bit Wₖ[X−1], and the weight switch SW2 is controlled by an inverse of the bit Wₖ[X−1] (i.e., W̅ₖ̅[̅X̅−̅1̅]̅), where the weight switch SW1 determines whether the analog input AOUTₖ (which is received from the switched-on global selection switch SWₖ) is passed to the charge-domain passive summation circuit (particularly, capacitor 2^{X-1}C of weighted capacitor array 112), and the weight switch SW2 determines whether a reference voltage (e.g., ground voltage) is passed to the charge-domain passive summation circuit (particularly, capacitor 2^{X-1}C of weighted capacitor array 112). It should be noted that the weight switches SW1 and SW2 are not switched on at the same time. That is, the weight switch SW2 is switched off during a period in which the weight switch SW1 is switched on, and the weight switch SW1 is switched off during a period in which the weight switch SW2 is switched on.

The cell selection switch SW3 is also a local selection switch integrated with each memory cell 114. In this embodiment, the candidate weights CW₁-CW_{Y} may be stored in memory cell lines (e.g., memory cell rows or memory cell columns), respectively. The cell selection switches SW3 integrated with the memory array 108 may be categorized into a plurality of cell selection switch groups that correspond to the memory cell lines (e.g., memory cell rows or memory cell columns), respectively. Hence, each of the cell selection switch groups includes cell selection switches SW3, each having one terminal that is coupled to the charge-domain passive summation circuit (particularly, one capacitor of weighted capacitor array 122). For example, the cell selection switch SW3 of the memory cell that stores the bit Wₖ[X−1] has one terminal coupled to the capacitor 2^{X-1}C of the weighted capacitor array 112, the cell selection switch SW3 of the memory cell that stores the bit Wₖ[0] has one terminal coupled to the capacitor 1C of the weighted capacitor array 112, and so on. In this embodiment, cell selection switches of one of the cell selection switch groups that corresponds to a memory cell line (e.g., memory cell row or memory cell column) in which the target weight Wₖ is stored are switched on, and cell selection switches of the rest of the cell selection switch groups are switched off. For example, cell selection switches SW3 of a cell selection switch group that corresponds to a memory cell line (e.g., memory cell row or memory cell column) in which the candidate weight Wⱼ is stored are switched off. Though the candidate weight Wⱼ is not selected as the target weight Wₖ, the memory cells that store bits of the candidate weight Wⱼ may include cell parasitic capacitance C_{par_cell}. By switching off the cell selection switches SW3, the power dissipation resulting from cell parasitic capacitance C_{par_cell} of memory cells that stores bits of the candidate weight Wⱼ (which is not selected as the target weight Wₖ) can be prevented to achieve energy reduction/power saving.

As shown in FIG. 1, the external analog buffers (e.g., digital-to-analog converters) 10_1-10_Z generates analog inputs AOUT₁-AOUT_{z} of the processing circuits 102_1-102_Z, respectively. Ideally, when two digital codes (e.g., DIN₁ and DIN₂) are the same, the corresponding analog inputs (e.g., AOUT₁ and AOUT₂) received by the CIM circuit 100 should be the same. However, inter-buffer mismatch may exist between different analog buffers due to imperfection of circuit components. As a result, the output voltage VOUT (which is an analog output of Σₖ₌₁^{Z}DINₖ×Wₖ[X−1:0]) may deviate from a correct voltage level. In a case where the CIM circuit 100 is used by an AI application, the classification accuracy may be degraded due to the inter-buffer mismatch. To address this issue, the CIM circuit 100 is further involved in calibration of external analog buffers (e.g., digital-to-analog converters) 10_1-10_Z.

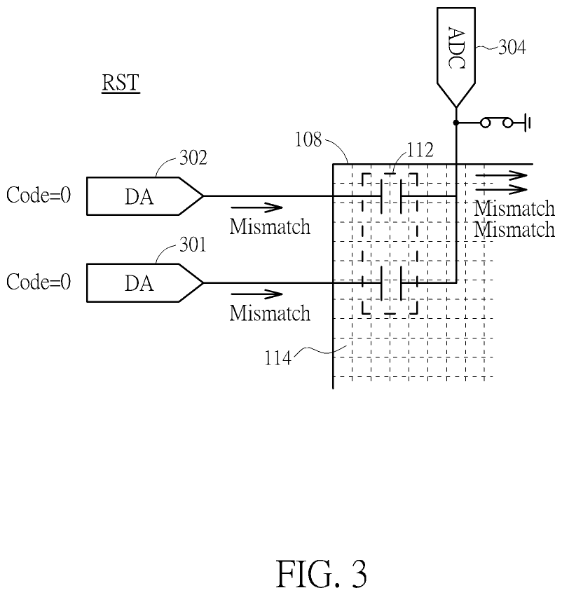

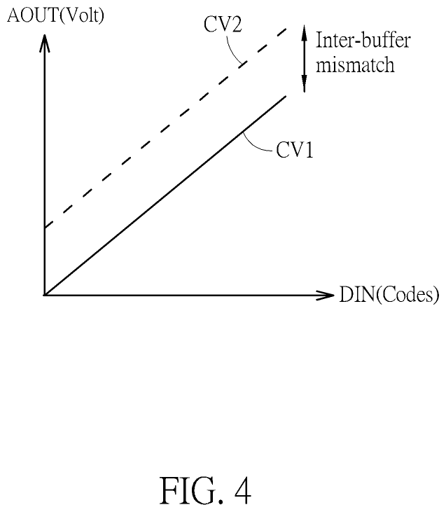

Please refer to FIG. 3 and FIG. 4. FIG. 3 is a diagram illustrating calibration of different external analog buffers of a CIM circuit according to an embodiment of the present invention. FIG. 4 is a diagram illustrating inter-buffer mismatch between different external analog buffers. The external analog buffer 301 may be one of the external analog buffers (e.g., digital-to-analog converters) 10_1-10_Z shown in FIG. 1. The external analog buffer 302 may be another of the external analog buffers (e.g., digital-to-analog converters) 10_1-10_Z shown in FIG. 1. Due to imperfection of circuit components, the transfer curve CV1 of the external analog buffer 301 is different from the transfer curve CV2 of the external analog buffer 302. Hence, the calibration of the external analog buffers 301 and 302 may include cancelling inter-buffer mismatch between the external analog buffers 301 and 302. For example, an auto-zeroing technique may be employed for inter-buffer mismatch cancellation. In some embodiments of the present invention, each of the external analog buffers 301 and 302 may be a discrete-time buffer. The discrete-time operation of the external analog buffer 301/302 may include a first phase in which the external analog buffer 301/302 operates in a reset (RST) mode and a second phase in which the external analog buffer 301/302 operates in a buffer (BUF) mode. The calibration of the external analog buffers 301 and 302 is performed during a period in which both of the external analog buffers 301 and 302 operate in the RST mode. As shown in FIG. 3, the same digital input (e.g., digital code=0) is fed into both of the external analog buffers 301 and 302, and a ground voltage is applied to top plates of capacitors included in the weighted capacitor array 112. In this way, the inter-buffer mismatch between the external analog buffers 301 and 302 is stored in the weighted capacitor array 112 when the external analog buffers 301 and 302 operate in the RST mode, and can be subtracted from the output voltage VOUT (which is an analog output of Σₖ₌₁^{Z}DINₖ×Wₖ[X−1:0]) when the external analog buffers 301 and 302 operate in the BUF mode. Since the inter-buffer mismatch between the external analog buffers 301 and 302 can be cancelled by auto-zeroing, the external analog buffers 301 and 302 may be regarded as having the same transfer curve (i.e., CV1=CV2) after calibration.

However, it is possible that the same transfer curve possessed by the external analog buffers 301 and 302 after auto-zeroing may still deviate from an ideal curve. To address this issue, the calibration of the external analog buffers 301 and 302 may further include aligning a transfer curve of each of the external analog buffers 301 and 302 with a predetermined curve.

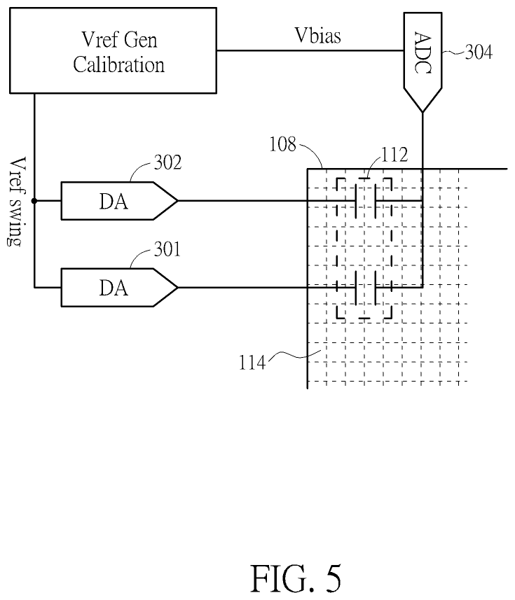

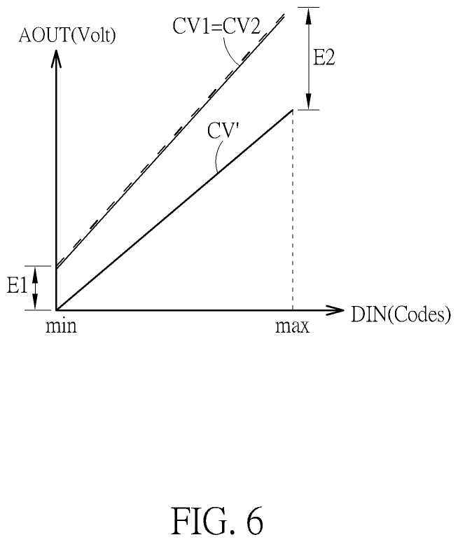

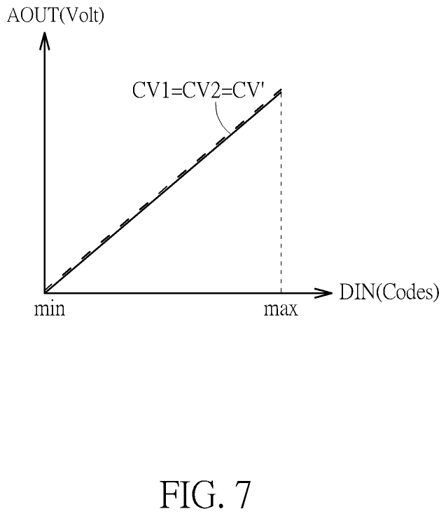

Please refer to FIG. 5, FIG. 6, and FIG. 7. FIG. 5 is a diagram illustrating additional calibration of different external analog buffers of a CIM circuit according to an embodiment of the present invention. FIG. 6 is a diagram illustrating deviation between aligned transfer curves of the external analog buffers 301 and 302 and an ideal curve CV′ before reference voltage tuning. FIG. 7 is a diagram illustrating that the aligned transfer curves of the external analog buffers 301 and 302 are the same as the ideal curve CV′ after reference voltage tuning. The minimum digital input (e.g., minimum code min) is applied to the external analog buffers 301 and 302, and a global offset E1 is obtained by the ADC 304, where a bias voltage Vbias of the ADC 304 is generated from a reference voltage generator. In addition, the maximum digital input (e.g., maximum code max) is applied to the external analog buffers 301 and 302, and a gain error E2 is obtained by the ADC 304. As shown in FIG. 5, reference voltage generator calibration (labeled by “Vref Gen Calibration”) is performed for tuning the reference voltages Vref used by the external analog buffers 301 and 302. In this way, the external analog buffers 301 and 302 can have the same transfer curve (which results from auto-zeroing) aligned with the ideal curve CV′ through reference voltage tuning.

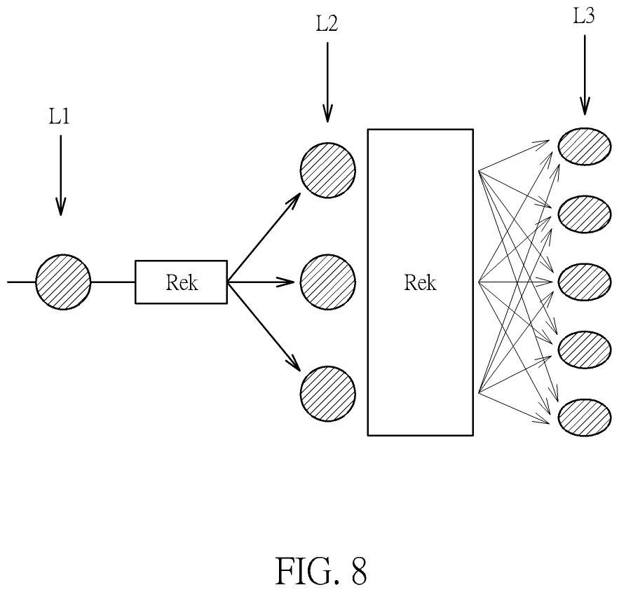

As mentioned above, the proposed CIM circuit 100 may be employed by an AI application. For example, the AI application may employ a CNN with multiple layers, and the proposed CIM circuit 100 maybe used by a neuron in one layer and reused by a neuron in another layer. In some embodiments of the present invention, per-layer calibration may be employed for tracking process, voltage, temperature (PVT) variation. FIG. 8 is a diagram illustrating per-layer calibration of different external analog buffers of a CIM circuit according to an embodiment of the present invention. In this embodiment, the neural network includes a plurality of layers such as L1, L2, and L3 shown in FIG. 8. The same CIM circuit 100 may be shared among different layers L1, L2, and L3. The aforementioned calibration (labeled by “ReK”) of different external analog buffers (e.g., external analog buffers 301 and 302 shown in FIG. 3 and FIG. is performed per layer, thereby making the external analog buffers 301 and 302 have the same transfer curve aligned with the ideal curve CV′. With the help of the per-layer calibration, a PVT insensitive ACIM circuit can be achieved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A compute-in-memory (CIM) circuit comprising:
a first processing circuit, comprising:
a first data-selection circuit, comprising:
a first memory array, arranged to store a plurality of candidate weights; and
a first selection circuit, arranged to select a first target weight from the plurality of candidate weights stored in the first memory array; and
a first charge-domain passive summation circuit, arranged to generate a first analog computation result of a first input received by the first processing circuit and the first target weight stored in the first memory array through a first weighted capacitor array integrated with the first memory array.

2. The CIM circuit of claim 1, wherein the plurality of candidate weights are weights of a neural network.

3. The CIM circuit of claim 1, wherein the first input of the first processing circuit is a single analog signal generated from an external analog buffer.

4. The CIM circuit of claim 1, wherein the first target weight comprises a plurality of bits, and the plurality of bits are stored in a plurality of memory cells in the memory array, respectively.

5. The CIM circuit of claim 4, wherein the first weighted capacitor array comprises a plurality of capacitors; and the first selection circuit is further arranged to selectively apply the first input to the plurality of capacitors according to the plurality of bits, respectively.

6. The CIM circuit of claim 5, wherein the first selection circuit is further arranged to control transmission of the first input by referring to the plurality of bits concurrently.

7. The CIM circuit of claim 1, further comprising:
a second data-selection circuit, comprising:
a second memory array, arranged to store the plurality of candidate weights; and
a second selection circuit, arranged to select a second target weight from the plurality of candidate weights stored in the second memory array; and
a second charge-domain passive summation circuit, arranged to generate a second analog computation result of a second input received by the second processing circuit and the second target weight stored in the second memory array through a second weighted capacitor array integrated with the second memory array;
wherein the first weighted capacitor array comprises a plurality of first capacitors each having a first plate and a second plate;
the second weighted capacitor array comprises a plurality of second capacitors each having a first plate and a second plate; and first plates of the plurality of first capacitors are connected to first plates of the second capacitors.

8. The CIM circuit of claim 7, wherein the plurality of candidate weights are weights of a neural network.

9. The CIM circuit of claim 1, wherein the first weighted capacitor array of the first charge-domain passive summation circuit is shared among the plurality of candidate weights stored in the first memory array.

10. The CIM circuit of claim 1, wherein the first memory array comprises a plurality of memory cell lines arranged to store the plurality of candidate weights, respectively; the first selection circuit comprises:
a plurality of global selection switches, corresponding to the plurality of memory cell lines, respectively, wherein each of the plurality of global selection switches has one terminal that is arranged to receive the first input, and one of the plurality of global selection switches that corresponds to a memory cell line in which the first target weight is stored is switched on.

11. The CIM circuit of claim 10, wherein the rest of the plurality of global selection switches are switched off.

12. The CIM circuit of claim 1, wherein the plurality of memory cells comprise a plurality of first memory cells arranged to store a plurality of bits of the first target weight; and for each of the plurality of bits of the first target weight, the first selection circuit comprises:
a first switch, controlled by the bit, wherein the first switch determines whether the first input is passed to the first charge-domain passive summation circuit; and
a second switch, controlled by an inverse of the bit, wherein the second switch determines whether a reference voltage is passed to the first charge-domain passive summation circuit.

13. The CIM circuit of claim 1, wherein the first memory array comprises a plurality of memory cell lines arranged to store the plurality of candidate weights, respectively; the first selection circuit comprises:
a plurality of cell selection switch groups, corresponding to the plurality of memory cell lines, respectively, wherein each of the plurality of cell selection switch groups comprises cell selection switches, each having one terminal that is coupled to the first charge-domain passive summation circuit; and cell selection switches of one of the plurality of cell selection switch groups that corresponds to a memory cell line in which the first target weight is stored are switched on.

14. The CIM circuit of claim 13, wherein cell selection switches of the rest of the plurality of cell selection switch groups are switched off.

15. The CIM circuit of claim 1, further comprising:
a second data-selection circuit, comprising:
a second memory array, arranged to store the plurality of candidate weights; and
a second selection circuit, arranged to select a second target weight from the plurality of candidate weights stored in the second memory array; and
a second charge-domain passive summation circuit, arranged to generate a second analog computation result of a second input received by the second data-selection circuit and the second target weight stored in the second memory array through a second weighted capacitor array integrated with the second memory array;
wherein the first data-selection circuit receives the first input from a first external analog buffer, and the second data-selection circuit receives the second input from a second external analog buffer; and
wherein the CIM circuit is further involved in calibration of the first external analog buffer and the second external analog buffer.

16. The CIM circuit of claim 15, wherein the calibration of the first external analog buffer and the second external analog buffer comprises cancelling inter-buffer mismatch between the first external analog buffer and the second external analog buffer.

17. The CIM circuit of claim 16, wherein the calibration of the first external analog buffer and the second external analog buffer further comprises aligning a transfer curve of each of the first external analog buffer and the second external analog buffer with a predetermined curve.

18. The CIM circuit of claim 15, wherein a neural network includes a plurality of layers, the CIM circuit is used by each of the plurality of layers, and the calibration of the first external analog buffer and the second external analog buffer is performed per layer.

19. A compute-in-memory (CIM) method comprising:
storing a plurality of candidate weights in a memory array;
selecting a target weight from the plurality of candidate weights; and
performing, by a weighted capacitor array integrated with the memory array, charge-domain passive summation to generate an analog computation result of an input and the target weight.

20. The CIM method of claim 19, wherein the plurality of candidate weights are weights of a neural network.
